(19) United States
(12) Patent Application Publication
(10) Pub. No.: US 2013/0162278 A1
(43) Pub. Date: Jun. 27, 2013

(54) PROBE PIN, PROBE CARD USING THE PROBE PIN, AND METHOD OF MANUFACTURING THE PROBE CARD

(71) Applicants: Doo Yun CHUNG, Seoul (KR); Dae Hyeong Lee, Seoul (KR); Ki Pyo Hong, Suwon (KR); Won Chul Ma, Suwon (KR); Yong Seok Choi, Suwon (KR)

(72) Inventors: Doo Yun CHUNG, Seoul (KR); Dae Hyeong Lee, Seoul (KR); Ki Pyo Hong, Suwon (KR); Won Chul Ma, Suwon (KR); Yong Seok Choi, Suwon (KR)

(73) Assignee: Samsung Electro-Mechanics Co., Ltd.

(21) Appl. No.: 13/532,475

(22) Filed: Jun. 25, 2012

(30) Foreign Application Priority Data
Dec. 22, 2011 (KR) 10-2011-0140024

(51) Int. Cl. G01R 1/067; B23K 31/02; B23K 1/20; G01R 1/073

(52) U.S. Cl. 324/755.01; 324/756.03; 228/165

(57) ABSTRACT

There is provided a probe card, including: a substrate having a plurality of grooves formed in one surface thereof; and at least one probe pin having a plurality of substrate combining protrusions formed on one surface thereof and corresponding to the plurality of grooves, the plurality of substrate combining protrusions having heights corresponding to the plurality of grooves.

### CROSS-REFERENCE TO RELATED APPLICATIONS

This application claims the priority of Korean Patent

Application No. 10-2011-0140024 filed on Dec. 22, 2011, in the Korean Intellectual Property Office, the disclosure of which is incorporated herein by reference.

### BACKGROUND OF THE INVENTION

1. Field of the Invention

The present invention relates to a probe pin, a probe card using the probe pin, and a method of manufacturing the probe card.

2. Description of the Related Art

Due to the recent development of integrated semiconductor circuit technology, the miniaturization of semiconductor devices has proceeded continuously, and thus, semiconductor chip testing apparatuses are required to be highly precise.

Integrated circuit chips, formed on a semiconductor wafer through a wafer fabrication process, are commonly classified as good products and defective products through electrical die sorting (EDS), a process conducted while the integrated circuit chips are present on the semiconductor wafer.

A test apparatus, consisting of a tester for generating test signals and determining test results, a probe station for loading or unloading a semiconductor wafer, and a probe card for electrically connecting the semiconductor wafer and the tester, is most commonly used in this electric die sorting.

Among these elements, the probe card mainly employs a structure in which the probe pin is combined with a ceramic substrate, which is manufactured by forming a circuit pattern, via electrodes, and the like, on respective ceramic green sheets, and laminating and firing these sheets.

However, as the probe card has recently been miniaturized, adhesion strength between the probe pin and the substrate may be weakened during a process of combining the probe pin and the substrate, with the result that the probe pin and the substrate may be separated from each other while the probe card is used.

Meanwhile, in the manufacturing method of the related art probe card, the probe pin and the substrate are bonded to each other by coating a combinatorial surface of the probe pin or the substrate with a predetermined solder, followed by soldering. Here, the solder may be coated on an unnecessary portion of the probe pin or the substrate during this process, or the solder may flow outwardly onto the substrate, and therefore, workability may be deteriorated in the process of preventing these problems.

### SUMMARY OF THE INVENTION

An aspect of the present invention provides a probe pin, a probe card using the probe pin, and a method of manufacturing the probe card, in which adhesion strength between a probe pin and a substrate may be secured, and workability may be improved in a process of combining the probe pin and the substrate.

According to an aspect of the present invention, there is provided a probe pin having a plurality of substrate combining protrusions formed on one surface thereof.

The plurality of substrate combining protrusions may be two substrate combining protrusions having different sizes, and may be protruded from one surface of the probe pin while being spaced apart from each other.

The substrate combining protrusions may be protruded from one surface of the probe pin at positions alternating with each other in a length direction thereof.

According to another aspect of the present invention, there is provided a probe card, including: a substrate having a plurality of grooves formed in one surface thereof; and at least one probe pin having a plurality of substrate combining protrusions formed on one surface thereof and corresponding to the plurality of grooves, the plurality of substrate combining protrusions having heights corresponding to the depth of the plurality of grooves.

The groove of the substrate may include a solder part formed therein and including at least one of tin (Sn) and silver-tin (Ag—Sn).

The substrate may further include: a plurality of via electrodes each having one end exposed through one surface of the substrate; and a circuit pattern electrically connected to the exposed one ends of of the respective via electrodes.

The grooves of the substrate and the substrate combining protrusions of the probe pin may be formed at positions alternating with each other in a length direction of the probe pin, respectively.

The substrate may further include a protective insulating layer covering one surface of the substrate.

The protective insulating layer may include penetration holes formed at portions corresponding to the grooves of the substrate.

According to another aspect of the present invention, there is provided a method of manufacturing a probe card, including: preparing a substrate; forming a plurality of grooves in one surface of the substrate; forming a solder part in of the respective grooves by injecting a solder material including at least one of tin (Sn) and silver-tin (Ag—Sn) so as to fill at least apart of the groove; and combining the probe pin with the substrate by respectively fitting the plurality of substrate combining protrusions of the probe pin into the plurality of grooves so as to be combined with each other and melting the solder material.

The grooves of the substrate and the substrate combining protrusions of the probe pin may be formed alternately with each other in a length direction of the probe pin, respectively.

The preparing of the substrate may include arranging a ceramic substrate including a plurality of via electrodes each having one end exposed through one surface of the substrate.

The method may further include, after the forming of the via electrodes, forming a circuit pattern electrically connecting the exposed one ends of the via electrodes to electrode pads.

The method may further include, after the forming of the circuit pattern, forming a protective insulating layer on one surface of the substrate.

The forming of the protective insulating layer may include forming penetration holes formed at portions thereof corresponding to the grooves of the substrate.

### BRIEF DESCRIPTION OF THE DRAWINGS

The above and other aspects, features and other advantages of the present invention will be more clearly understood from the following detailed description taken in conjunction with the accompanying drawings, in which:

FIG. 1 is a perspective view showing a probe pin according to an embodiment of the present invention;

FIG. 2A is a bottom view of the probe pin of FIG. 1;

FIGS. 2A and 2C are bottom views of probe pins according to several embodiments of the present invention;

FIG. 3 is a cross sectional view schematically showing a probe card according to an embodiment of the present invention;

FIGS. 4A to 4F are process cross sectional views showing a method of manufacturing a probe substrate according to an embodiment of the present invention;

FIG. 5 is a cross sectional view schematically showing a probe card according to another embodiment of the present invention; and

FIG. 6 is a cross sectional view schematically showing a probe card according to another embodiment of the present invention.

### DETAILED DESCRIPTION OF THE EMBODIMENTS

Hereinafter, embodiments of the present invention will be described in detail with reference to the accompanying drawings.

However, the invention may be embodied in many different forms and should not be construed as being limited to the embodiments set forth herein.

The embodiments of the present invention are provided so that those skilled in the art may more completely understand the present invention.

In the drawings, the shapes and dimensions may be exaggerated for clarity, and the same reference numerals will be used throughout to designate the same or like components.

In addition, like reference numerals denote parts performing similar functions and actions throughout the drawings.

In addition, unless explicitly described otherwise, “comprising” any components will be understood to imply the inclusion of other components but not the exclusion of any other components.

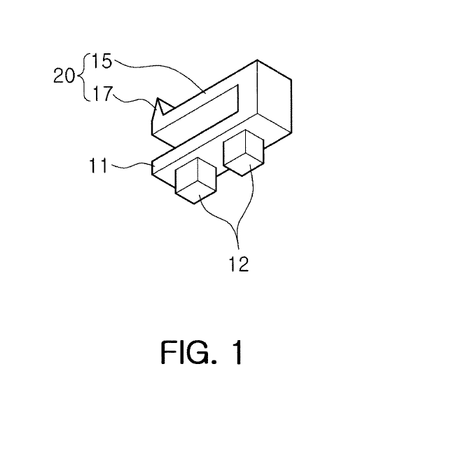

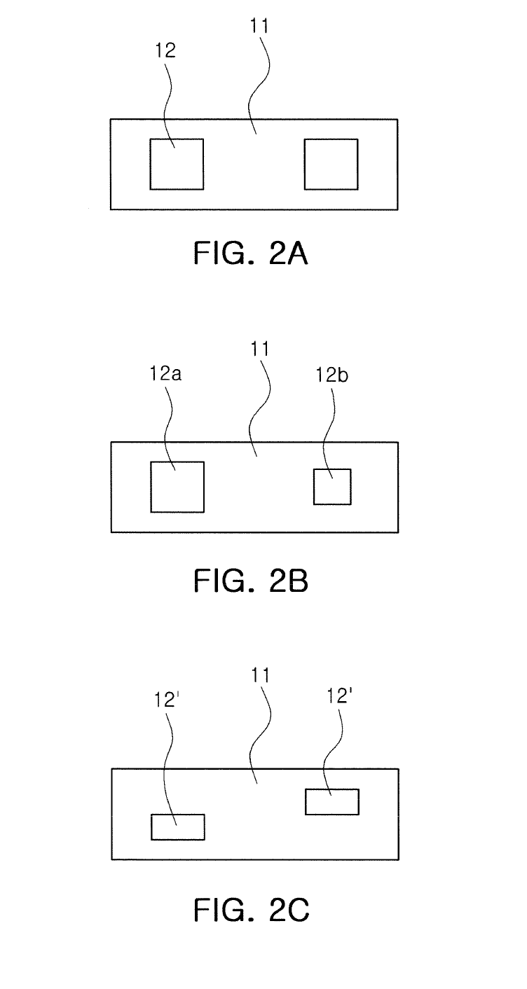

Referring to FIGS. 1 and 2A, a probe pin 20 according to an embodiment of the present invention may include a plurality of protrusions 12 for combining with a substrate, formed on one surface thereof. The protrusions 12 may be inserted in groove portions of a ceramic substrate to be later described so as to improve adhesion strength with the ceramic substrate.

In the present embodiment, the probe pin 20 may be manufactured by using a micro thin substrate technology applied in semiconductor manufacture, and may include, for example, a cantilever type combination part 11, a body part 15, and a contact part 17.

Among them, the combination part 11 may have a square plate shape, and two protrusions 12 each having a square pillar shape may be protruded from a bottom surface of the combination part 11.

Here, the number of protrusions 12 may be variously changed depending on the shape, the size, and the like of the probe pin. Also, the shape of the protrusion 12 is not limited to the square pillar shape shown in the drawing, and may be variously changed to a circular pillar shape, a triangular pillar shape, or the like, depending on application of the probe pin.

In addition, one end of the body part 15 may be connected to one end of the combination part 11.

Here, the body part 15 is not limited to the shape shown in the drawing, and the shape of the body part 15 may be variously changed, as necessary.

That is, in the present embodiment, the shape of the probe pin 20 is not limited to the cantilever shape, and may be variously changed depending on the shape, the size, and the like of the probe card. For example, the probe pin may be formed in a straight line shape by being combined perpendicularly to the ceramic substrate.

In the present embodiment, the body part 15 may have a cantilever structure, and the contact part 17 may be connected to the other end of the body part 15.

The contact part 17 may have a ‘V’ shape or a tip shape constituting a cutting edge so that an end portion of the contact part 17 may be contacted with an object (not shown) such as a wafer die.

In other words, the contact part 17 may be contacted with the object, and thus may serve to transmit an electric signal received from a test apparatus to the object and again transmit a signal received from the object to the probe card 10.

FIGS. 2B and 2C show probe pins according to other embodiments of the present invention.

Referring to FIG. 2B, a probe pin 20 according to another embodiment may have two protrusions 12a and 12b having different sizes and protruded while being spaced apart from each other.

For this reason, according to the present embodiment, front and rear installation directions of the probe pin 20 may be prevented from being reversed when the probe pin 20 is combined with the ceramic substrate to be later described.

In addition, referring to FIG. 2C, the probe pin 20 according to another embodiment may have two protrusions 12′ which are located at positions alternating with each other in a length direction of the combination part 11.

For this reason, according to the present embodiment, adhesion strength between the probe pin 20 and the ceramic substrate may be relatively more improved when the probe pin 20 is combined with the ceramic substrate to be later described.

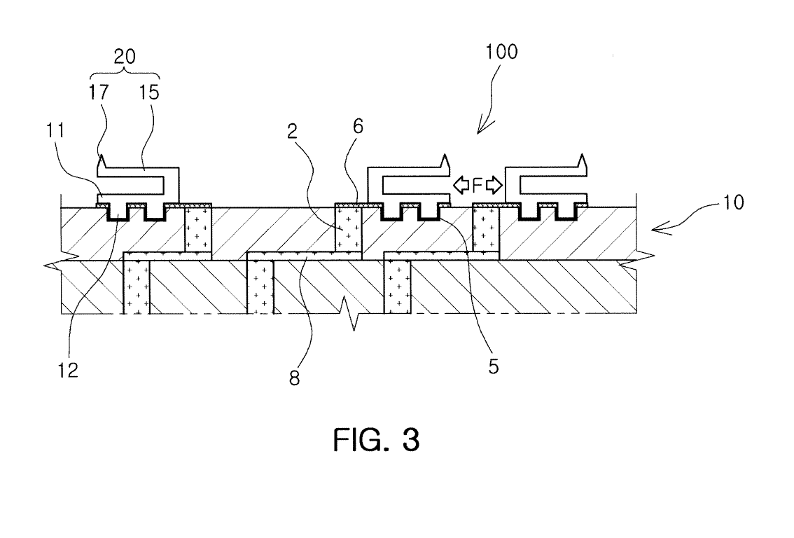

FIG. 3 shows a probe card according to an embodiment of the present invention, manufactured by using the above probe pin.

Referring to FIG. 3, a probe card 100 according to an embodiment of the present invention may include a probe substrate 10, and a plurality of probe pins 20 combined with one surface of the probe substrate 10 and physically and electrically connected to the probe substrate 10.

A plurality of grooves 3 may be formed in one surface of the probe substrate 10 such that protrusions 12 of the probe pin 20 are combined to the grooves 3. This protrusion 12 of the probe pin 20 may have a height corresponding to a depth of the groove 3 so that a combination part 11 of the probe pin 20 is not separated from but closely contacted with one surface of the probe substrate 10 when the protrusion 12 is combined with the groove 3.

Here, as shown in FIGS. 2B and 2C, in cases where the protrusions 12a and 12b of the probe pin 20 have different sizes or the protrusions 12′ of the probe pin 20 are alternately positioned in a length direction of the probe pin 20, the grooves 3 of the ceramic substrate 10 also may be constituted at positions corresponding to the grooves 3 and may have shapes corresponding to the grooves 3.

The probe substrate 10 (hereinafter, for convenience of explanation, the probe substrate and the ceramic substrate will be used and described together, but the two substrates are designated as the same component) may be manufactured by laminating a plurality of ceramic green sheets and then firing them.

The ceramic substrate 10 may have a plurality of ceramic layers formed by these ceramic green sheets, and each ceramic layer may have a plurality of wiring patterns 8 and a plurality of via electrodes 2 perpendicularly connected to the wiring patterns.

Also, a circuit pattern 6 may be formed on one surface of the ceramic substrate 10 such that the probe pin 20 is electrically connected thereto through the via electrode 2 connected to an inside of the ceramic substrate 10.

Through this combining structure of protrusion/groove, the probe pin 20 may be contacted with the ceramic substrate 10 by a more increased contact area in the present embodiment, as compared with the combining structure of the probe pin and the ceramic substrate in the related art.

In other words, the related art discloses that only corresponding combining surfaces of the ceramic substrate 10 and the probe pin 20 are contacted with each other, whereas according to the present embodiments, the contact area of the probe pin 20 and the ceramic substrate 10 is increased by a total area of the protrusions 12 protruded from the probe pin 20. In addition, according to the present embodiment, since the protrusion 12 of the probe pin 20 is embedded in the ceramic substrate 10, adhesion strength between the probe pin 20 and the ceramic substrate 10 may be improved.

As such, the probe pin 20 of the related art is combined with the ceramic substrate 10 through simple surface contact, whereas a lateral wall of the groove 3 formed in the ceramic substrate 10 supports the protrusion 12 of the probe pin 20, resulting in a relative excellent adhesion strength between the probe pin 20 and the ceramic substrate 10 in the present embodiment. Therefore, unexpected separation of the probe pin from the ceramic substrate 10 may be prevented notwithstanding application of force in an F direction, as shown in FIG. 3.

Hereinafter, a method of manufacturing a probe card 100 according to an embodiment of the present invention will be described.

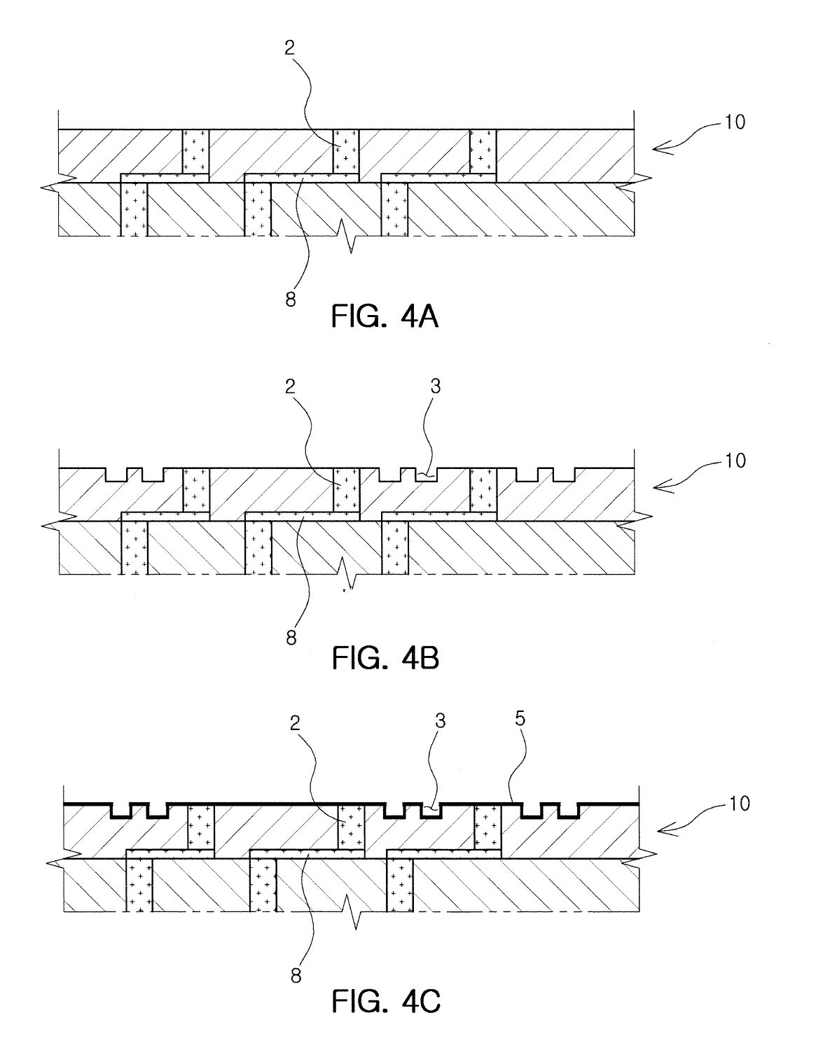

FIGS. 4A to 4F are process cross sectional views showing a method of manufacturing a probe substrate according to an embodiment of the present invention.

First, as shown in FIG. 4A, there is prepared a ceramic substrate 10 in which a plurality of ceramic layers are laminated and sintered.

Wiring patterns 8 and via electrodes 2 may be formed in the plurality of ceramic layers constituting the ceramic substrate 10.

Here, the ceramic substrate 10 maybe a low-temperature co-fired ceramic (hereinafter, referred to as ‘LTCC’) substrate 10.

The LTCC substrate 10 may be formed by preparing ceramic green sheets through a doctor blade process or the like, forming the via electrodes 2 and the wiring patterns 8 in the respective ceramic green sheets, and then laminating and sintering the resultant ceramic green sheets. Here, the sintering process may be performed at a temperature of about 700 to 900° C.

Next, as shown in FIG. 4B, a plurality of grooves 3 may be formed in one surface of the ceramic substrate 10.

Here, the method of forming the grooves 3 is not particularly limited. For example, a laser drilling method, a chemical etching method, or the like may be used, but the present invention is not limited thereto.

Next, as shown in FIG. 4C, a seed layer 5 formed of a metal material may be formed on one surface of the ceramic substrate 10.

The seed layer 5 may be formed in a thin film type on the ceramic substrate 10.

Also, the seed layer 5 may be formed of a conductive material. The seed layer 5 may be formed of a material that can be easily combined with a material for forming a circuit pattern 6 formed on the ceramic substrate 10 or the probe pin 20 and can have relatively high adhesion strength therewith. For example, the seed layer 5 may be formed of at least one metal selected from titanium (Ti), chrome (Cr), nickel (Ni), copper (Cu), silver (Ag) and gold (Au).

This seed layer 5 may be provided in order to strongly combine the circuit pattern 6 with the ceramic substrate 10 when the circuit pattern 6 is formed.

This seed layer 5 may be formed in a thin film type on the ceramic substrate 10 by using sputtering, aerosol, e-beam, or the like.

In addition, the seed layer 5 may be formed by using a cold spray coating method under the high-pressure argon (Ar), helium (He), and nitrogen (N₂) atmosphere. However, the present invention is not limited thereto.

Next, the grooves 3 may be filled with a metal layer. Here, an electroplating process may be performed, and plating may be performed on the entire surface thereof without a separate mask. A difference in thickness occurring herein may be controlled through a planarizing work. This work serves to improve process stability.

Next, as shown in FIG. 4D, a PR layer 7 may be formed on one surface of the ceramic substrate 10.

The PR layer 7 may serve to designate a position at which the circuit pattern 6 is formed on the ceramic substrate 10. The circuit pattern 6 is not formed in a portion in which the PR layer 70 is formed, which will be described later.

In other words, when the PR layer 7 is formed on the grooves 3, the PR layer 7 prevents the circuit pattern 6 from being formed, so that upper sides of the grooves 3 may be kept in an open state.

Next, as shown in FIG. 4E, a metal layer 60 may be formed. The forming of the metal layer 60 may be performed by an electroplating method.

In other words, the metal layer 60 may be grown on the seed layer 5 by impregnating the ceramic substrate 10 in an electrolytic liquid, and then applying voltage to the seed layer 5 having conductivity.

In the present embodiment, since the seed layer 5 is formed on the whole of one surface of the ceramic substrate 10, the electroplating method may be easily applied. Here, the metal layer 60 may be formed while the metal layer 60 is not contacted with the seed layer 5 on the portion in which the PR layer 7 is formed.

The method of forming the metal layer 7 according to the embodiment of the present invention is not limited to this electroplating method. The metal layer 7 maybe formed by using various methods such as an electroless plating method, screen printing, sputtering, and the like, as necessary.

Next, when the PR layer 7 is stripped out, the circuit pattern 6 may be selectively formed while the metal layer 60 partially remains on one surface of the ceramic substrate 10.

The circuit pattern 6 may be formed such that the vial electrode 20 and the probe pin 2 are electrically connected to each other.

When the probe substrate 10 according to the present embodiment is completed through the above procedure, the protrusions 12 of the probe pin 20 may be combined with the grooves 3 of the ceramic substrate 10, so that the combination part 11 of the probe pin 2 is closely contacted with the upper surface of the circuit pattern 6. As a result, a probe card according to the present embodiment may be completed as shown in FIG. 3.

As for the probe card according to the present embodiment, constituted as above, has a structure in which the protrusions 12 of the probe pin 20 are fitted to and combined with the grooves 3 of the ceramic substrate 10, and thus, adhesion strength between the probe pin 20 and the ceramic substrate 10 may be improved.

Meanwhile, the probe card and the method of manufacturing the same, according to embodiments of the present invention, are not limited to the above-described embodiments, and various applications may be provided.

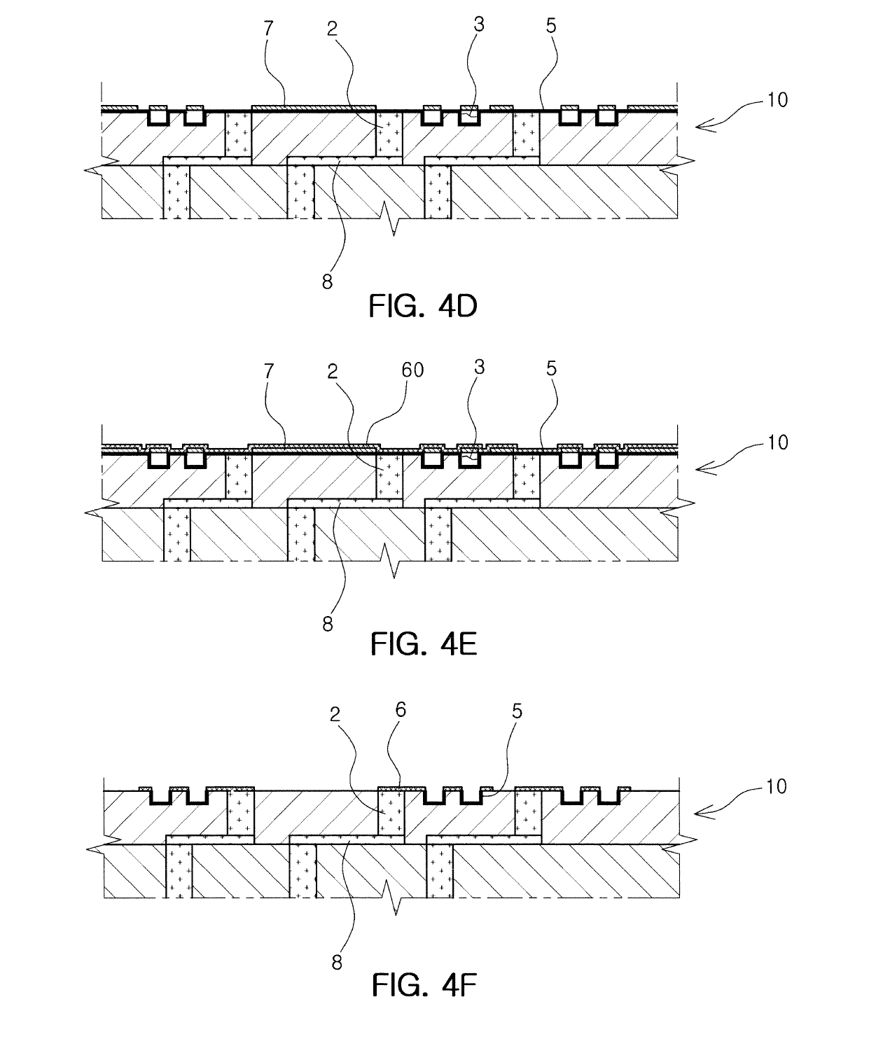

FIG. 5 is a cross sectional view schematically showing a probe card according to another embodiment of the present invention. The probe card 200 according to the present embodiment has a similar constitution as the probe card 100 of the above-described embodiment. However, the probe card 200 according to the present embodiment is different from the probe card 100 of the above-described embodiment in view of only a structure of a protective insulating layer 9.

Accordingly, detailed descriptions of the same components will be omitted, and a structure of the protective insulating layer 9 will be mainly described in detail. The same reference numerals will be used for the same components in the above-described embodiment.

Referring to FIG. 5, the probe card 200 according to the present embodiment may include a probe substrate 10 and a probe pin 20.

In addition, the probe substrate 10 may include a ceramic substrate 10 and a protective insulating layer 9.

The protective insulating layer 9 may be disposed on the uppermost portion of the ceramic substrate 10 to serve to protect one surface of the ceramic substrate 10.

Here, the protective insulating layer 9 may have penetration holes through which protrusions 12 of the probe pin 20 pass.

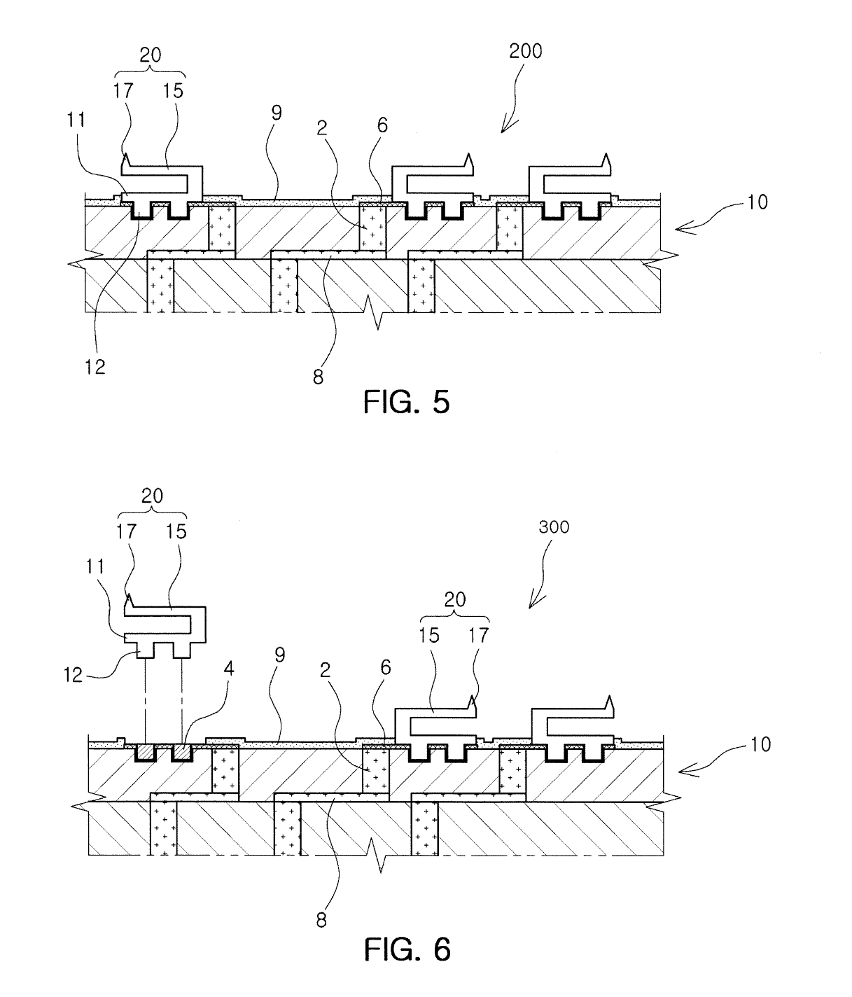

FIG. 6 is a cross sectional view schematically showing a probe card according to another embodiment of the present invention. The probe card 300 according to an embodiment of the present invention has a similar structure to the probe card 200 of the above-described embodiment. However, the probe card 300 according to the present embodiment is different from the probe card 200 of the above-described embodiment in view of only a structure of a solder part 4.

Accordingly, detailed descriptions of the same components will be omitted, and a structure of the solder part 4 will be mainly described in detail. The same reference numerals will be used for the same components in the above-described embodiment.

Referring to FIG. 6, the probe card 300 according to the present embodiment may include a probe substrate 10 and a probe pin 20.

In addition, a solder part 4 may be formed in the groove 3 of the probe substrate 10 by filling the groove 3 with a solder material including at least one material of tin (Sn), silver-tin (Ag—Sn), and the like.

Therefore, when the solder part 4 is previously heated at the time of combination of the probe pin 20, a process of coating a separate solder material on the protrusion 12 of the probe pin 12 may be omitted, resulting in a simplified process. In addition, the solder material filling the solder part flows out while the protrusion 12 of the probe pin 20 is fitted in the groove 3, and thereby to be soldered around the protrusion 12, and thus, adhesion strength between the probe pin 20 and the ceramic substrate 10 may be relatively more improved.

As set forth above, according to the embodiments of the present invention, the probe pin and the substrate are combined in a protrusion/groove combination structure, and thus, unexpected separation of the probe pin from the substrate may be prevented.

The present invention is not limited to the above-described embodiments and the accompanying drawings, but defined by the accompanying claims.

Accordingly, various forms of substitutions, modifications and alterations may be made by those skilled in the art without departing from the spirit of the prevent invention defined by the accompanying claims. These substitutions, modifications and alterations are considered as being within the scope of the present invention.

While the present invention has been shown and described in connection with the embodiments, it will be apparent to those in the art that modifications and variations may be made without departing from the spirit and scope of the invention as defined by the appended claims.

What is claimed is:

1. A probe pin having a plurality of substrate combining protrusions formed on one surface thereof.

2. The probe pin of claim 1, wherein the plurality of substrate combining protrusions are two substrate combining protrusions having different sizes, and are protruded from one surface of the probe pin while being spaced apart from each other.

3. The probe pin of claim 1, wherein the substrate combining protrusions are protruded from one surface of the probe pin at positions alternating with each other in a length direction thereof.

4. A probe card, comprising:
a substrate having a plurality of grooves formed in one surface thereof; and
at least one probe pin having a plurality of substrate combining protrusions formed on one surface thereof and corresponding to the plurality of grooves, the plurality of substrate combining protrusions having heights corresponding to the depth of the plurality of grooves.

5. The probe card of claim 4, wherein the groove of the substrate includes a solder part formed therein and including at least one of tin (Sn) and silver-tin (Ag—Sn).

6. The probe card of claim 4, wherein the substrate further includes:
a plurality of via electrodes each having one end exposed through one surface of the substrate; and
a circuit pattern electrically connected to the exposed one ends of the respective via electrodes.

7. The probe card of claim 4, wherein the grooves of the substrate and the substrate combining protrusions of the probe pin are formed at positions alternating with each other in a length direction of the probe pin, respectively.

8. The probe card of claim 4, wherein the substrate further includes a protective insulating layer covering one surface of the substrate.

9. The probe card of claim 8, wherein the protective insulating layer has penetration holes formed at portions corresponding to the grooves of the substrate.

10. A method of manufacturing a probe card, comprising:
preparing a substrate;
forming a plurality of grooves in one surface of the substrate;
forming a solder part in the respective grooves by injecting a solder material including at least one of tin (Sn) and silver-tin (Ag—Sn) so as to fill at least a part of the groove; and
combining the probe pin with the substrate by respectively fitting the plurality of substrate combining protrusions of the probe pin into the plurality of grooves so as to be combined with each other and melting the solder material.

11. The method of claim 10, wherein the grooves of the substrate and the substrate combining protrusions of the probe pin are formed alternately with each other in a length direction of the probe pin, respectively.

12. The method of claim 10, wherein the preparing of the substrate includes arranging a ceramic substrate including a plurality of via electrodes each having one end exposed through one surface of the substrate.

13. The method of claim 12, further comprising, after the forming of the via electrodes, forming a circuit pattern electrically connecting the exposed one ends of the via electrodes to electrode pads.

14. The method of claim 13, further comprising, after the forming of the circuit pattern, forming a protective insulating layer on one surface of the substrate.

15. The method of claim 14, wherein the forming of the protective insulating layer includes forming penetration holes formed at portions thereof corresponding to the grooves of the substrate.
